(19) United States
(12) Patent Application Publication
(10) Pub. No.: US 2026/0315941 A1
(43) Pub. Date: Oct. 15, 2026

(54) TOY HOUSE

(71) Applicant: EPOCH COMPANY, LTD., Tokyo (JP)

(72) Inventor: Kei KAMIYAMA, Tokyo (JP)

(73) Assignee: EPOCH COMPANY, LTD., Tokyo (JP)

(21) Appl. No.: 19/644,845

(22) Filed: Apr. 10, 2026

(30) Foreign Application Priority Data
Apr. 14, 2025 (JP) 2025-066238

(51) Int. Cl. A63H 3/52

(52) U.S. Cl. CPC A63H 3/52

(57) ABSTRACT

A toy house includes a house body, and an accessory toy. The accessory toy includes a stepped part having a stair shape on a first surface and a slide part having a slide surface on a second surface. The accessory toy is usable as a toy stair in a first state in which the accessory toy is attached to the house body. The accessory toy is usable as a toy slide in a second state in which the accessory toy is attached to the house body in an up-down direction opposite to that in the first state. In the second state, a first length of a lower surface of the accessory toy along an extending direction of a lower part of the slide surface is longer than a second length of an upper surface of the accessory toy along an extending direction of an upper part of the slide surface.

### CROSS-REFERENCE TO RELATED APPLICATIONS

This application is based on and claims priority under 35 USC 119 from Japanese Patent Application No. 2025-066238 filed on Apr. 14, 2025, the contents of which are incorporated herein by reference.

### TECHNICAL FIELD

The present disclosure relates to a toy house.

### BACKGROUND ART

Patent Literature 1 discloses a toy house including an accessory toy capable of transforming a climbing toy such as a ladder into a toy slide. The accessory toy disclosed in Patent Literature 1 has a climbing surface including a plurality of rod-shaped steps on one surface of a main plate member, and has a slide surface and a climbing surface for a slide on the other surface.

Then, the accessory toy can be played as a climbing toy in a state where the accessory toy is attached to a toy house body with the climbing surface of the accessory toy facing outward. In addition, the accessory toy can be played as a toy slide by removing the accessory toy from the toy house body and bending a boundary between the slide surface and the climbing surface for the slide in a state where the slide surface and the climbing surface for the slide face outward.

### Citation List

### Patent Literature

Patent Literature 1: JP2025-023378A

### SUMMARY OF INVENTION

It is conceivable to use a toy stair imitating a stair as a toy slide instead of the climbing toy imitating a ladder as disclosed in Patent Literature 1. However, since the toy stair has a plurality of stepped shapes, it is difficult to implement a configuration in which a part of the toy stair is bent to have both a slide surface and a climbing surface for a slide as disclosed in Patent Literature 1.

Therefore, in order to play as a toy slide even in a toy having a structure without a climbing surface for a slide, it is conceivable to install the toy slide to connect floor surfaces having different heights in a house body part.

However, when the toy stair is also used as a toy slide to be attached to the house body, while a step corresponding to one stair is required between a first step of the toy stair and the floor surface of the house body, a configuration in which there are few steps between a lower surface of the toy slide and the floor surface of the house body is desired.

A toy house according to the present disclosure includes a house body; and an accessory toy that is attachable to and detachable from the house body. The accessory toy is provided with a stepped part having a stair shape on a first surface and a slide part having a slide surface on a second surface facing the first surface, the accessory toy is usable as a toy stair in a first state in which the accessory toy is attached to the house body with the stepped part facing outward, and the accessory toy is usable as a toy slide in a second state in which the accessory toy is attached to the house body, with the slide part facing outward, in an up-down direction opposite to that in the first state. In the second state, a first length of a lower surface of the accessory toy along an extending direction of a lower part of the slide surface is longer than a second length of an upper surface of the accessory toy along an extending direction of an upper part of the slide surface.

According to the above configuration, the toy stair can also be used as a toy slide to be attached to the house body, and a difference between a floor surface of the house body and a lower end of the slide surface of the toy slide can be reduced.

### BRIEF DESCRIPTION OF DRAWINGS

FIG. 1 is a rear view of a toy house according to an embodiment of the present disclosure;

FIG. 2 is a perspective view (part 1) illustrating a configuration of an accessory toy illustrated in FIG. 1;

FIG. 3 is a partially enlarged view illustrating a first state in which the accessory toy illustrated in FIG. 2 is attached to a house body with a first surface of the accessory toy facing a front surface;

FIG. 4 is a perspective view (part 2) illustrating a configuration of the accessory toy illustrated in FIG. 1;

FIG. 5 is a partially enlarged view illustrating a second state in which the accessory toy illustrated in FIG. 4 is attached to the house body with a second surface of the accessory toy facing the front surface;

FIG. 6 is a partially enlarged view illustrating a detailed configuration of a first floor surface of the house body in a state where the accessory toy illustrated in FIG. 1 is removed; and

FIG. 7 is a partially enlarged view illustrating a detailed configuration of a second floor surface of the house body in a state where the accessory toy illustrated in FIG. 1 is removed.

### DESCRIPTION OF EMBODIMENTS

Hereinafter, an embodiment of the present disclosure will be described in detail with reference to the drawings. In the following description, the same components are denoted by the same reference numerals, and the names and functions thereof are the same. Therefore, detailed description thereof will not be repeated.

In the following description, the terms "front", "rear", "left", "right", "up", and "down" may be used, and these directions are relative directions set for convenience of description. In each drawing, "F" represents "front", "B" represents "rear", "L" represents "left", "R" represents "right", "U" represents "up", and "D" represents "down".

### Overall Configuration of Toy House

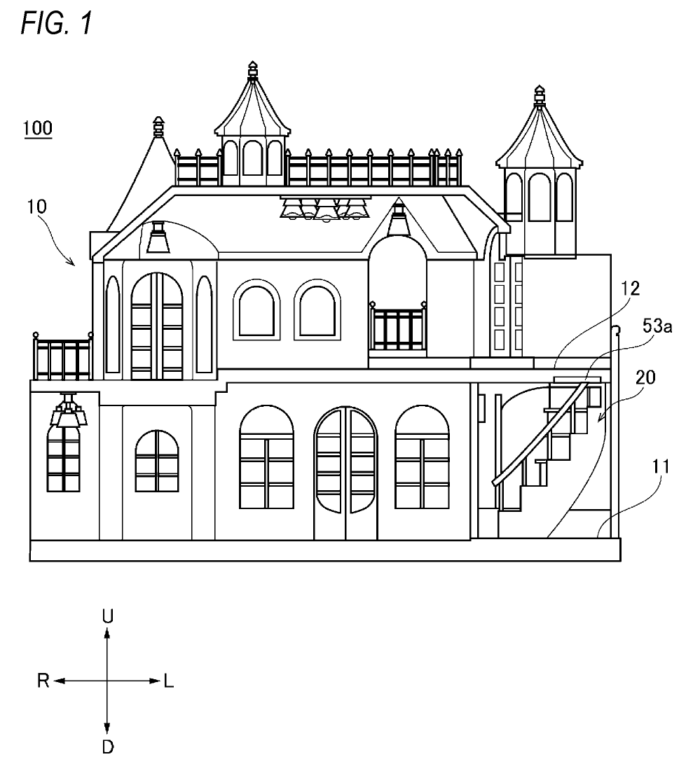

FIG. 1 is a rear view of a toy house 100 according to an embodiment of the present disclosure. The toy house 100 includes, for example, a house body 10 imitating a two-story building and an accessory toy 20 that is attachable to and detachable from the house body 10.

The house body 10 is open on a rear side, and a player can place a toy or the like imitating furniture inside the house body 10 from the rear side of the house body 10 to play a doll or the like. As illustrated in FIG. 1, the accessory toy 20 can be used as a toy stair that couples a first floor and a second floor of the house body 10.

### Detailed Configuration of Accessory Toy

### Configuration of First Surface

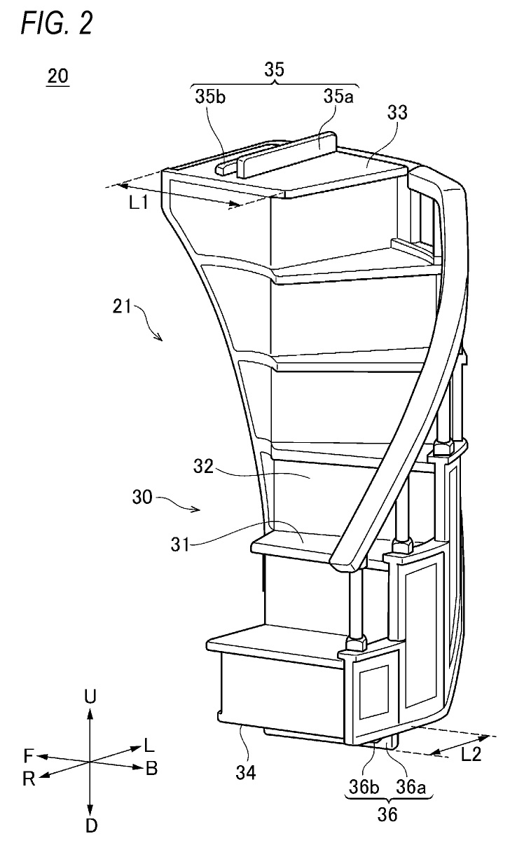

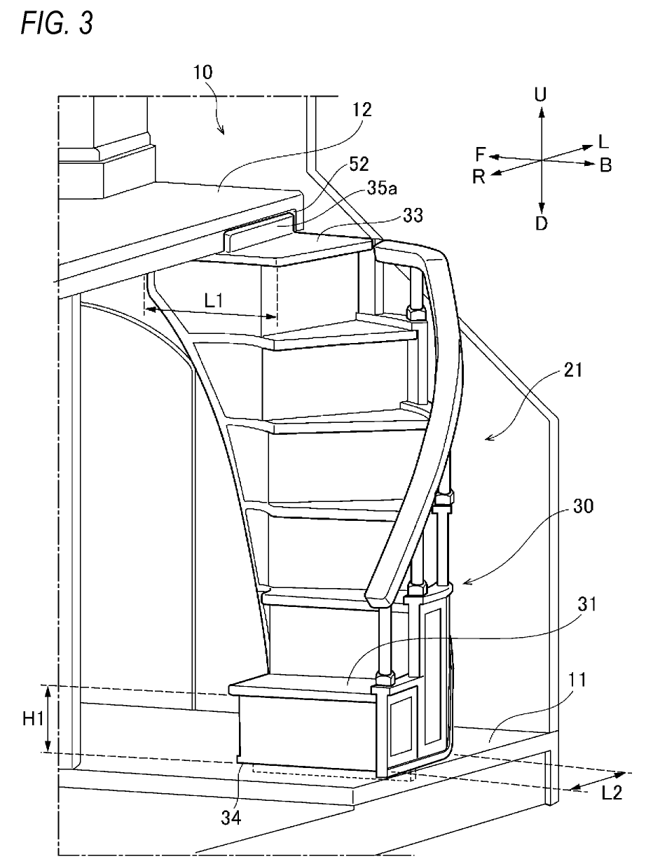

FIG. 2 is a perspective view (part 1) illustrating a configuration of the accessory toy 20 illustrated in FIG. 1. The accessory toy 20 has a first surface 21. FIG. 3 is a partially enlarged view illustrating a first state in which the accessory toy 20 illustrated in FIG. 2 is attached to the house body 10 with the first surface 21 of the accessory toy 20 facing a front surface.

As illustrated in FIGS. 2 and 3, the first surface 21 is provided with a stepped part 30 having a stair shape. The player can attach the accessory toy 20 to the house body 10 in the first state illustrated in FIG. 3 to use the accessory toy 20 as a toy stair.

More specifically, the stepped part 30 includes a plurality of tread board parts 31 provided at different heights from one another, and a plurality of riser board parts 32 coupling the tread board parts 31 continuous in an up-down direction.

The stepped part 30 has, for example, a shape imitating a spiral stair, and is curved to draw an arc in a top view. Specifically, an upper surface 33 of the stepped part 30 extends in a front-rear direction, and a lower surface 34 of the stepped part 30 extends in a left-right direction.

Here, the upper surface 33 of the stepped part 30 extending in the front-rear direction means that the riser board part 32 coupled to the upper surface 33 among the plurality of riser board parts 32 extends in the left-right direction and a direction from an upper end of the riser board part 32 toward a back side of the upper surface 33 is the front-rear direction. In addition, the lower surface 34 of the stepped part 30 extending in the left-right direction means that the riser board part 32 coupled to the lower surface 34 extends in the front-rear direction and a direction from a lower end of the riser board part 32 toward a back side of the lower surface 34 is the left-right direction. A length L1 in a depth direction (that is, front-rear direction) of the upper surface 33 of the stepped part 30 is longer than a length L2 in a depth direction (that is, left-right direction) of the lower surface 34 of the stepped part 30.

Further, the upper surface 33 of the stepped part 30 is provided with a first protrusion 35 that protrudes upward in the first state. The first protrusion 35 includes a first rear protrusion 35a and a first front protrusion 35b. The first rear protrusion 35a is provided near a center of the upper surface 33 of the stepped part 30 in the depth direction (that is, front-rear direction). The first front protrusion 35b is provided in front of the first rear protrusion 35a in the first state.

The first rear protrusion 35a and the first front protrusion 35b have, for example, a plate shape and extend in the left-right direction in the first state. A height of the first front protrusion 35b is lower than a height of the first rear protrusion 35a.

### Configuration of Second Surface

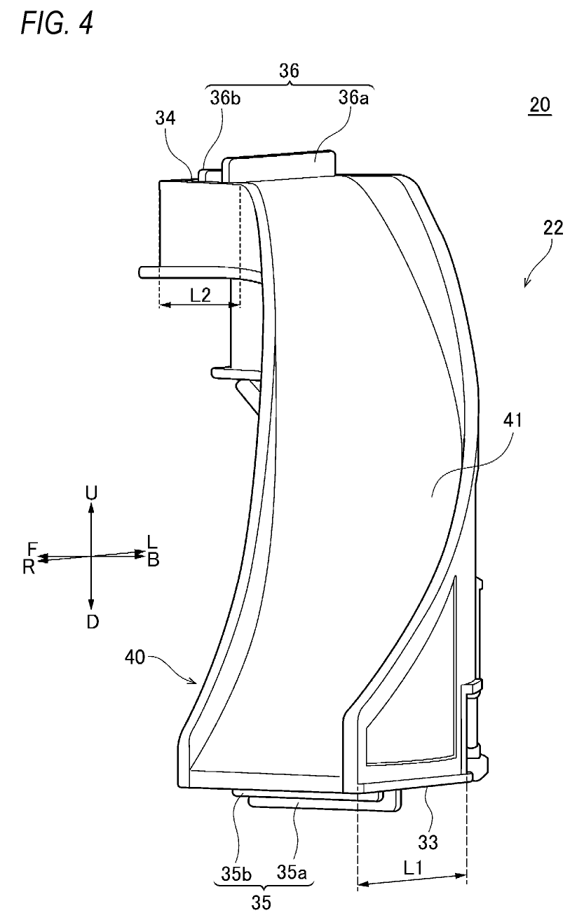

FIG. 4 is a perspective view (part 2) illustrating a configuration of the accessory toy 20 illustrated in FIG. 1. The accessory toy 20 has a second surface 22 facing the first surface 21 illustrated in FIG. 2. For example, when the player rotates the accessory toy 20 by 180 degrees along an axis along the left-right direction from a state where the first surface 21 of the accessory toy 20 is the front surface, the second surface 22 of the accessory toy 20 becomes the front surface as illustrated in FIG. 4. The "front surface" in the present example means the rear side of the house body 10.

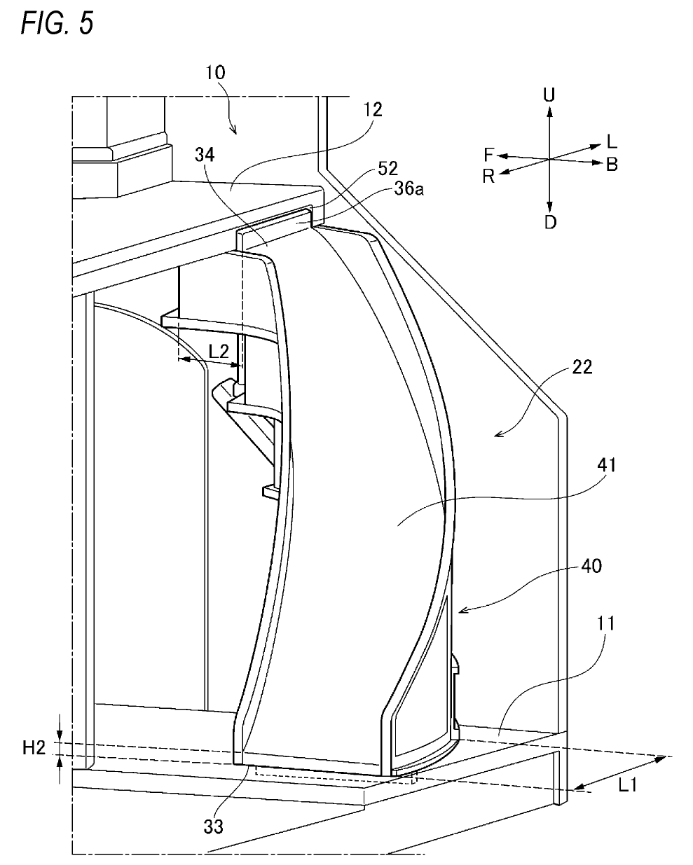

FIG. 5 is a partially enlarged view illustrating a second state in which the accessory toy 20 illustrated in FIG. 4 is attached to the house body 10 with the second surface 22 of the accessory toy 20 facing the front surface. As illustrated in FIGS. 4 and 5, the second surface 22 is provided with a slide part 40 having a slide surface 41.

The player can attach the accessory toy 20 to the house body 10 in the second state illustrated in FIG. 5 to use the accessory toy 20 as a toy slide. That is, the accessory toy 20 can serve as both a toy stair to be attached to the house body 10 and a toy slide to be attached to the house body 10.

More specifically, the slide part 40 is curved to draw an arc in the top view. Specifically, as illustrated in FIG. 4, the upper surface 34 of the slide part 40 corresponds to the lower surface 34 of the stepped part 30 illustrated in FIG. 2, and extends in the front-rear direction. The lower surface 33 of the slide part 40 corresponds to the upper surface 33 of the stepped part 30 illustrated in FIG. 2, and extends in the left-right direction.

As described above, the length L1 in the depth direction of the lower surface 33 of the slide part 40 (that is, length L1 along extending direction of a lower part of slide surface 41) is longer than the length L2 in the depth direction of the upper surface 34 of the slide part 40 (that is, length L2 along extending direction of upper part of slide surface 41).

Further, the upper surface 34 of the slide part 40 is provided with a second protrusion 36 that protrudes upward in the second state. The second protrusion 36 includes a second rear protrusion 36a and a second front protrusion 36b. The second rear protrusion 36a is provided on the rear side of the upper surface 34 of the slide part 40. The second front protrusion 36b is provided in front of the second rear protrusion 36a in the second state.

The second rear protrusion 36a and the second front protrusion 36b have, for example, a plate shape and extend in the left-right direction in the second state. A height of the second front protrusion 36b is lower than a height of the second rear protrusion 36a.

### Attachment Structure of House Body and Accessory Toy

### Attachment when Used as Toy Stair

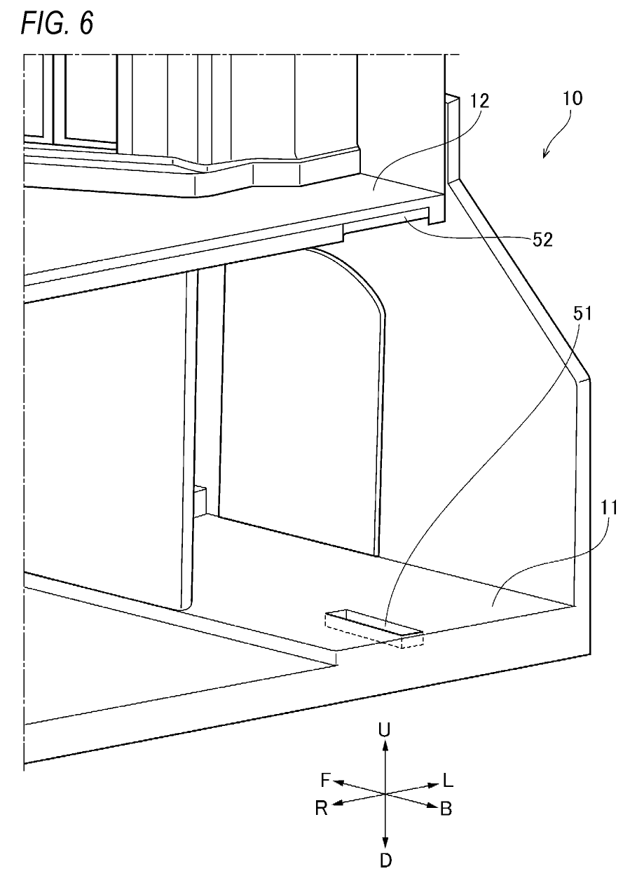

FIG. 6 is a partially enlarged view illustrating a detailed configuration of a first floor surface 11 of the house body 10 in a state where the accessory toy 20 illustrated in FIG. 1 is removed. A first recess 51 is formed in the first floor surface 11 of the house body 10. The first recess 51 has, for example, a rectangular parallelepiped shape extending in the front-rear direction of the house body 10, and an upper surface of the first recess 51 is open.

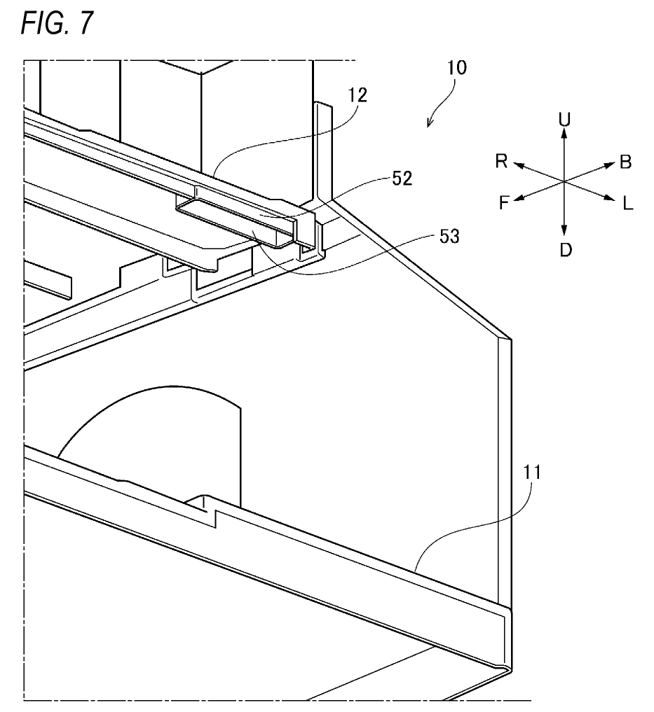

FIG. 7 is a partially enlarged view illustrating a detailed configuration of a second floor surface 12 of the house body 10 in a state where the accessory toy 20 illustrated in FIG. 1 is removed. As illustrated in FIG. 7, a fitting portion 52 having, for example, a rectangular recessed shape is formed on an end surface on a rear side of the second floor surface 12. The fitting portion 52 extends in the left-right direction. A length of the fitting portion 52 in the left-right direction is, for example, slightly longer than a length of the first rear protrusion 35a in the left-right direction illustrated in FIG. 2 and a length of the second rear protrusion 36a in the left-right direction illustrated in FIG. 4.

A second recess 53 is provided in front of the fitting portion 52 on a lower surface of the second floor surface 12. The second recess 53 has, for example, a rectangular parallelepiped shape extending in the left-right direction of the house body 10, and a lower surface of the second recess 53 is open. A length of the second recess 53 in the left-right direction is, for example, the same as the length of the fitting portion 52 in the left-right direction.

When the accessory toy 20 is used as a toy stair, the player causes the first rear protrusion 35a of the accessory toy 20 to abut against the fitting portion 52 of the second floor surface 12 as illustrated in FIG. 3. In addition, the player inserts the first front protrusion 35b (see FIG. 2) of the accessory toy 20 from a lower surface of the second recess 53 (see FIG. 7) in the second floor surface 12 into the second recess 53 to fit the first front protrusion 35b into the second recess 53.

As described above, since the first front protrusion 35b is lower than the first rear protrusion 35a, the first front protrusion 35b is easily inserted into the second recess 53. In addition, since the first rear protrusion 35a abuts against the end surface of the second floor surface 12, it is possible to prevent rattling of the accessory toy 20 in a front-rear direction.

Further, the player inserts the second rear protrusion 36a and the second front protrusion 36b (see FIG. 4) of the accessory toy 20 into the first recess 51 from the upper surface of the first recess 51 (see FIG. 6) in the first floor surface 11 to cause the second rear protrusion 36a and the second front protrusion 36b to be fitted into the first recess 51. Accordingly, it is possible to prevent rattling of the accessory toy 20 in the front-rear direction and to stably attach the accessory toy 20 as a toy stair to the house body 10 without providing a large base in the accessory toy 20 itself. As illustrated in FIG. 3, in the first state, a step H1 between the tread board part 31 located at a lowest position and the first floor surface 11 can be set to a height of one stair.

### Attachment when Used as Toy Slide

When the accessory toy 20 is used as a toy slide, the player causes the second rear protrusion 36a of the accessory toy 20 to abut against the fitting portion 52 of the second floor surface 12 as illustrated in FIG. 5. In addition, the player inserts the second front protrusion 36b (see FIG. 4) of the accessory toy 20 into the second recess 53 from the lower surface of the second recess 53 (see FIG. 7) in the second floor surface 12 to cause the second front protrusion 36b to be fitted into the second recess 53.

As described above, since the second front protrusion 36b is lower than the second rear protrusion 36a, the second front protrusion 36b is likely to be inserted into the second recess 53. In addition, since the second rear protrusion 36a abuts against the end surface of the second floor surface 12, it is possible to prevent rattling of the accessory toy 20 in the front-rear direction.

Further, the player inserts the first rear protrusion 35a and the first front protrusion 35b (see FIG. 4) of the accessory toy 20 into the first recess 51 from the upper surface of the first recess 51 (see FIG. 6) in the first floor surface 11 to cause the first rear protrusion 35a and the first front protrusion 35b to be fitted into the first recess 51. Accordingly, it is possible to prevent rattling of the accessory toy 20 in the front-rear direction and to stably attach the accessory toy 20 as a toy slide to the house body 10.

In addition, as illustrated in FIG. 5, since the length L1 of the lower surface 33 of the slide part 40 is formed to be long, the slide surface 41 can extend to a position close to the first floor surface 11 of the house body 10 in the second state in which the accessory toy 20 is attached to the house body 10 such that the second surface 22 becomes the front surface. Accordingly, a step H2 between a lower end of the slide surface 41 and the first floor surface 11 can be reduced.

As described above, a toy house according to the present embodiment includes a house body and an accessory toy that is attachable to and detachable from the house body. The accessory toy is provided with a stepped part having a stair shape on a first surface and a slide part having a slide surface on a second surface facing the first surface. In addition, the accessory toy may be used as a toy stair in a first state in which the accessory toy is attached to the house body with the stepped part facing a front surface, and may be used as a toy slide in a second state in which the accessory toy is attached to the house body, with the slide part facing the front surface, in an up-down direction opposite to that in the first state. In the second state, a first length of a lower surface of the accessory toy along an extending direction of a lower portion of the slide surface is longer than a second length of an upper surface of the accessory toy along an extending direction of an upper portion of the slide surface.

With such a configuration, the toy stair attached to the house body and the toy slide attached to the house body can be combined as the accessory toy.

In addition, with the above configuration, it is possible to increase a first length of a lower surface of the slide part while setting a second length of an upper surface of the slide part (that is, depth of lowermost stair in first state) to a length similar to a depth of second and subsequent stairs. Therefore, the slide surface of the slide part can extend to a position close to a floor surface of the house body, and a difference between the floor surface of the house body and a lower end of the slide surface can be reduced.

In the toy house according to the present embodiment, the house body has a first floor surface and a second floor surface provided above the first floor surface. The accessory toy is attached to couple the first floor surface and the second floor surface. A first protrusion protruding upward is provided on an upper surface of the stepped part, and a second protrusion protruding downward is provided on a lower surface of the stepped part. A first recess is formed in the first floor surface, and a second recess is formed in the second floor surface. In the first state, the second protrusion is fitted into the first recess, and the first protrusion is fitted into the second recess. In the second state, the second protrusion is fitted into the second recess, and the first protrusion is fitted into the first recess.

With such a configuration, it is possible to stably attach the accessory toy to the house body without providing a large base or the like in the accessory toy, in both cases of using the accessory toy as a toy stair and using the accessory toy as a toy slide.

In the toy house according to the present embodiment, the first protrusion includes a first rear protrusion and a first front protrusion. The first front protrusion is lower than the first rear protrusion and is provided on a back side of the first rear protrusion in the first state. The second protrusion includes a second rear protrusion and a second front protrusion. The second front protrusion is lower than the second rear protrusion and is provided on the back side of the second rear protrusion in the second state.

In this manner, of the first rear protrusion and the first front protrusion of the first protrusion, the first front protrusion provided on the back side in the first state is lower than the first rear protrusion, so that when the accessory toy is attached to the house body to be in the first state, the first protrusion is likely to be fitted into the second recess.

In addition, of the second rear protrusion and the second front protrusion of the second protrusion, the second front protrusion provided on the back side in the second state is lower than the second rear protrusion, so that when the accessory toy is attached to the house body to be in the second state, the second protrusion is likely to be fitted into the second recess.

In the toy house according to the present embodiment, in the first state, the first rear protrusion abuts against an end surface of the second floor surface, and the first front protrusion is fitted into the second recess. In the second state, the second rear protrusion abuts against the end surface of the second floor surface, and the second front protrusion is fitted into the second recess.

With such a configuration, it is possible to prevent rattling of the accessory toy in a front-rear direction in a state in which the accessory toy is attached to the house body.

Although the present embodiment has been described above, the technical scope of the present invention should not be construed as being limited by the description of the present embodiment. It should be understood by those skilled in the art that the present embodiment is an example and various modifications of the embodiment are possible within the scope of the invention described in the claims. The technical scope of the present invention should be determined based on the scope of the invention described in the claims and the equivalent scope thereof.

What is claimed is:

1. A toy house comprising:
a house body; and
an accessory toy that is attachable to and detachable from the house body, wherein
the accessory toy is provided with a stepped part having a stair shape on a first surface and a slide part having a slide surface on a second surface facing the first surface,
the accessory toy is usable as a toy stair in a first state in which the accessory toy is attached to the house body with the stepped part facing outward,
the accessory toy is usable as a toy slide in a second state in which the accessory toy is attached to the house body, with the slide part facing outward, in an up-down direction opposite to that in the first state, and
in the second state, a first length of a lower surface of the accessory toy along an extending direction of a lower part of the slide surface is longer than a second length of an upper surface of the accessory toy along an extending direction of an upper part of the slide surface.

2. The toy house according to claim 1, wherein
the house body has a first floor surface and a second floor surface provided above the first floor surface,
the accessory toy is attached to couple the first floor surface and the second floor surface,
a first protrusion protruding upward is provided on an upper surface of the stepped part,
a second protrusion protruding downward is provided on a lower surface of the stepped part,
a first recess is formed in the first floor surface,
a second recess is formed in the second floor surface,
in the first state, the second protrusion is fitted into the first recess, and the first protrusion is fitted into the second recess, and
in the second state, the second protrusion is fitted into the second recess, and the first protrusion is fitted into the first recess.

3. The toy house according to claim 2, wherein
the first protrusion includes a first rear protrusion and a first front protrusion,
the first front protrusion is lower than the first rear protrusion and is provided on a back side of the first rear protrusion in the first state,
the second protrusion includes a second rear protrusion and a second front protrusion, and
the second front protrusion is lower than the second rear protrusion and is provided on the back side of the second rear protrusion in the second state.

4. The toy house according to claim 3, wherein
in the first state, the first rear protrusion abuts against an end surface of the second floor surface, and the first front protrusion is fitted into the second recess, and
in the second state, the second rear protrusion abuts against the end surface of the second floor surface, and the second front protrusion is fitted into the second recess.
